(19) United States
(12) Patent Application Publication
(10) Pub. No.: US 2026/0173726 A1
(43) Pub. Date: Jun. 18, 2026

(54) Display Device

(71) Applicant: LG Display Co., Ltd., Seoul (KR)

(72) Inventor: Choongkeun Yoo, Gimpo-si (KR)

(21) Appl. No.: 19/366,093

(22) Filed: Oct. 22, 2025

(30) Foreign Application Priority Data
Dec. 13, 2024 (KR) 10-2024-0185874

(51) Int. Cl. H10K 59/80; H10K 59/131; H10K 59/95

(52) U.S. Cl. CPC H10K 59/873; H10K 59/131; H10K 59/95

(57) ABSTRACT

A display device according to embodiments of the present specification includes a display panel including an active area and a pad area disposed at one side of the active area, a cover member disposed on the display panel and having a plurality of connection lines on a lower surface, and a chip-on-film which is bonded with the lower surface of the cover member and on which a driving chip is mounted. Here, one ends of the plurality of connection lines of the cover member may be connected to pads in the pad area of the display panel, and the other ends of the plurality of connection lines of the cover member may be connected to pads of the chip-on-film.

### CROSS REFERENCE TO RELATED APPLICATION

The present application claims priority to Republic of Korea Patent Application No. 10-2024-0185874, filed Dec. 13, 2024, the entire contents of which is incorporated herein for all purposes by this reference.

### TECHNICAL FIELD

The present specification relates to a display device.

### DESCRIPTION OF RELATED ART

There are advantages in that organic light emitting diode display devices as the self-luminous types have a wider viewing angle and a higher contrast ratio than liquid crystal display devices and are lighter and thinner and have low consumed power because they do not require a separate backlight. In addition, the organic light emitting diode display devices have the advantages of being capable of direct current (DC) low voltage driving, having a fast response time, and especially having the inexpensive manufacturing cost.

Recently, head mounted display devices including the organic light emitting diode display device have been developed. The head mounted display device can implement virtual reality (VR) or augmented reality (AR). A high resolution display panel is applied to the head mounted display device.

### SUMMARY OF THE INVENTION

A high resolution display panel applied to head-mounted display devices is required to have an ultra-high resolution of 4K or higher. To meet this requirement, OLEDoS (OLED on silicon) micro display devices, which form a backplane substrate including transistors on a silicon wafer and form organic light-emitting elements thereon, are being applied to display panels.

To drive ultra-high resolution display panels, a double-sided circuit chip-on-film (COF) with high circuit integration is used. Conventionally, the double-sided circuit COF is bonded with a pad area of a display panel. The double-sided circuit COF requires a via-hole area in which via-holes to connect upper-surface circuit lines to lower-surface circuit lines are disposed. When the double-sided circuit COF is bonded with the pad area of the display panel, the via-hole area of the double-sided circuit COF is located on a non-active area of the display panel, thereby increasing the non-active area of the display panel by the via-hole area. Accordingly, the number of backplane substrates that can be manufactured from a single silicon wafer, that is, unit per sheet (UPS) is decreased. This becomes a factor in increasing a manufacturing cost of the OLEDoS micro display device.

The present specification is directed to providing a display device in which a size of a non-active area of a display panel can be decreased.

The present specification is also directed to providing a display device in which unit per sheet (UPS) can be increased and a manufacturing cost can be decreased.

Objects of the present specification are not limited to the above-described objects, and other objects that are not mentioned will be able to be clearly understood by those skilled in the art based on the following description.

According to embodiments of the present specification, there is provided a display device including a display panel including an active area and a pad area disposed at one side of the active area, a cover member disposed on the display panel and having a plurality of connection lines on a lower surface, and a chip-on-film which is bonded with the lower surface of the cover member and on which a driving chip is mounted. Here, a first end of each of the plurality of connection lines of the cover member may be connected to a corresponding one of the pads in the pad area of the display panel, and a second end of each of the plurality of connection lines of the cover member may be connected to a corresponding one of the pads of the chip-on-film.

According to embodiments of the present specification, there is provided a display device including a display panel including an active area and a pad area disposed at one side of the active area, a cover member disposed on the display panel, and a chip-on-film electrically connected to the pad area of the display panel through the cover member.

According to the embodiments of the present specification, since the double-sided circuit COF having the via hole area is bonded with the cover member instead of the pad area of the display panel, it is possible to reduce the non-active area of the display panel. That is, it is possible to reduce the size of the backplane substrate that provides the pad area of the display panel.

According to the embodiments of the present specification, it is possible to reduce the size of the backplane substrate of the display panel, thereby increasing the number of backplane substrates of the display panel that can be manufactured from a single semiconductor substrate, that is, unit per sheet (UPS) and reducing the manufacturing cost of the display device.

According to the embodiments of the present specification, it is possible to increase the number of backplane substrates of the display panel, thereby reducing production energy required for manufacturing the display device and reducing greenhouse gas emission.

An additional embodiment of the present specification is directed to a display device having a display panel that includes an active area and a pad area disposed at one side of the active area. The display device also includes a cover member disposed on the display panel. The display device further includes a chip-on-film bonded with a lower surface of the cover member, the chip-on-film having a via hole area including a plurality of via holes. The via holes of the chip-on-film and the pad area of the display panel are non-overlapping in a plan view of the display device.

Effects of the present specification are not limited to the above-described effects, and other effects that are not mentioned will be able to be clearly understood by those skilled in the art based on the above detailed description.

### BRIEF DESCRIPTION OF THE DRAWINGS

FIG. 1 is a schematic plan view of a display device according to an embodiment of the present specification.

FIG. 2 is a cross-sectional view of the display device along line II-II in FIG. 1.

FIG. 3 is a schematic plan view of a display panel according to the embodiment of the present specification.

FIG. 4 is a schematic plan view of a chip-on-film COF applied to the display device according to the embodiment of the present specification.

FIG. 5 is a cross-sectional view of the display panel along line V-V in FIG. 3.

FIG. 6 is an enlarged view of area VI in FIG. 5.

FIG. 7 is a schematic cross-sectional view of an organic light-emitting layer according to one embodiment of the present specification.

FIG. 8 is a schematic plan view of the display device according to the embodiment of the present specification.

FIG. 9 is a schematic plan view of the display device according to the embodiment of the present specification.

FIGS. 10 to 12 show a head mounted display device according to one embodiment of the present specification.

### DETAILED DESCRIPTION OF THE INVENTION

Advantages and features of the present specification and methods for achieving them will become clear by referencing embodiments described below in detail in conjunction with the accompanying drawings. However, the present specification is not limited to the embodiments disclosed below but will be implemented in various different forms, these embodiments are merely provided to make the disclosure of the present specification complete and fully inform those skilled in the art to which the present specification pertains of the scope of the present specification.

Since shapes, sizes, ratios, angles, numbers, etc. disclosed in the drawings for describing the embodiments of the present specification are illustrative, the present specification is not limited to the shown items. The same reference number denotes the same components throughout the specification. In addition, in describing the present specification, when it is determined that the detailed description of a related known technology may unnecessarily obscure the gist of the present specification, the detailed description thereof will be omitted. When “comprise,” “have,” “consist of,” or the like described herein are used, other parts may be added unless “only” is used. When a component is expressed in a singular form, it includes a case in which the component is provided as a plurality of components unless specifically stated otherwise.

In construing a component, the component is construed as including a margin of error even when there is no separate explicit description related to the margin of error.

When the positional relationship is described, for example, when the positional relationship between two parts is described using “on,” “above,” “under,” “next to,” or the like, one or more other parts may be located between the two parts, for example, unless “immediately,” “directly,” or “close to” is used.

When the temporal relationship is described, when the temporal relationship is described using “after,” “subsequently,” “then,” “before,” or the like, it may also include a non-consecutive case unless “immediately” or “directly” is used.

Although terms such as first and second are used to describe various components, these components are not limited by these terms. These terms are only used to distinguish one component from another component. Therefore, a first component described below may be a second component within the technical spirit of the present specification.

In the description of components of the present specification, terms such as first, second, A, B, (a), and (b) may be used. These terms are only for the purpose of distinguishing one component from another component, and the nature, sequence, order, or the like of the corresponding component is not limited by these terms.

When a certain component is described as being “connected,” “coupled,” “joined,” or “attached” to another component, the certain component may be connected, coupled, joined, or attached directly to another component, but it should be understood that still another component may be interposed between components that may be connected, coupled, joined, or attached indirectly unless otherwise stated specially.

When a component or a layer is described as “coming into contact with” or “overlapping” another component or layer, the component or the layer may come into direct contact with or directly overlap another component or layer, but it should be understood that still another component may be interposed between components that may come into indirect contact with and indirectly overlap each other unless otherwise stated specially.

It should be understood that “at least one” includes any combination of one or more of associated components. For example, “at least one of first, second, and third components” may include not only the first, second, or third component, but also any combination of two or more of the first, second, and third components.

The terms “first direction,” “second direction,” “third direction,” “X-axis direction,” “Y-axis direction,” and “Z-axis direction” should not be construed as merely the geometric relationship in which the relationship therebetween is perpendicular and may refer to a wider directionality within the range in which the configuration of the present specification may act functionally.

Features of various embodiments of the present specification may be coupled or combined partially or entirely, various technological interworking and driving are made possible, and the embodiments may be implemented independently of each other or implemented together in an associated relationship.

Hereinafter, various embodiments of the present specification will be described in detail with reference to the accompanying drawings.

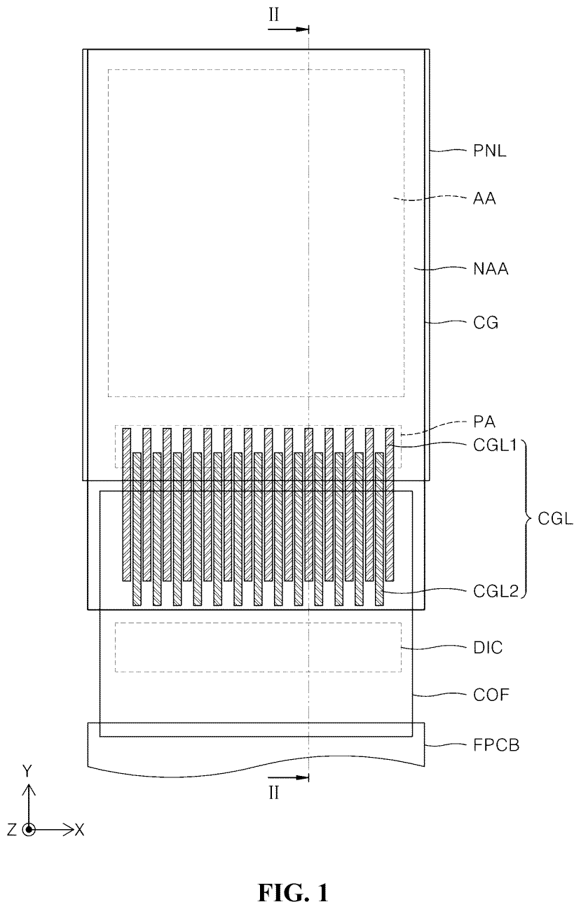

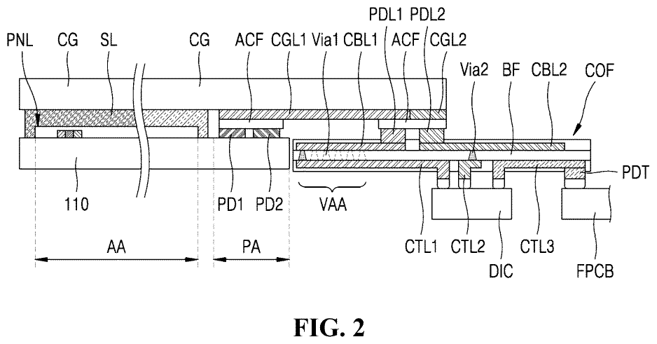

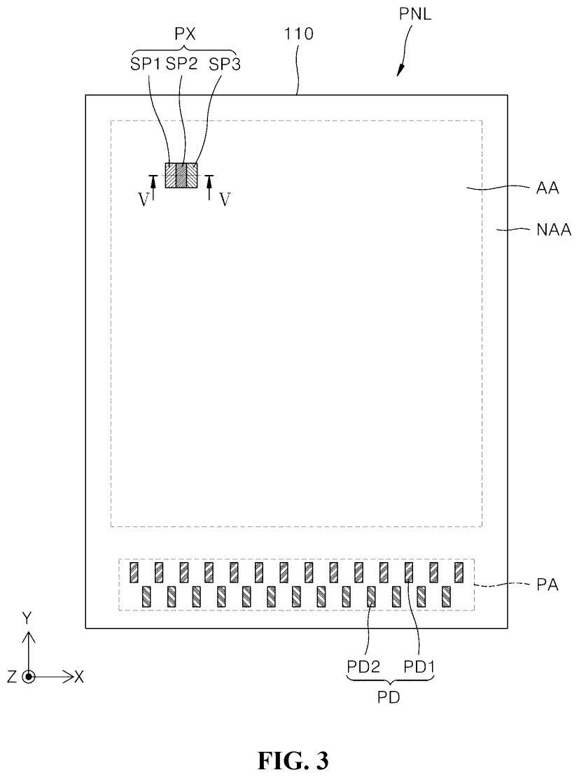

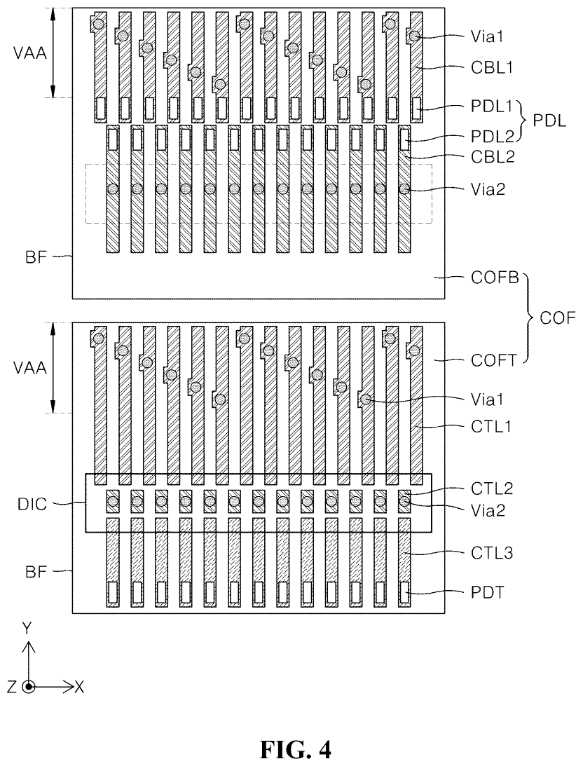

FIG. 1 is a schematic plan view of a display device according to an embodiment of the present specification. FIG. 2 is a cross-sectional view of the display device along line II-II in FIG. 1. FIG. 3 is a schematic plan view of a display panel according to the embodiment of the present specification. FIG. 4 is a schematic plan view of a chip-on-film COF applied to the display device according to the embodiment of the present specification. The top drawing of FIG. 4 represents a bottom surface COFB of the chip-on-film COF, and the bottom drawing of FIG. 4 represents a top surface COFT of the chip-on-film COF.

Referring to FIGS. 1, 2, and 3, a display device according to one embodiment of the present disclosure may include a display panel PNL, a cover member CG, a chip-on-film COF, and a flexible printed circuit board FPCB.

The display panel PNL may include an active area AA in which an image is implemented, and a non-active area NAA which is located outside the active area AA and in which an image is not implemented.

The active area AA of the display panel PNL may include a plurality of pixels PX. Each pixel PX may include a first sub-pixel SP1, a second sub-pixel SP2, and a third sub-pixel SP3. The non-active area NAA of the display panel PNL may include a pad area PA which is located at one side of the active area AA, for example, a lower side of the active area AA in a plan view, and in which a plurality of pads PD are disposed.

The plurality of pads PD may be arranged in a plurality of rows. The plurality of pads PD may include, for example, a plurality of first pads PD1 constituting a first row and a plurality of second pads PD2 constituting a second row. The plurality of first pads PD1 and the plurality of second pads PD2 may be alternately disposed such that the ends of the first pads PD1 and the second pads PD2 are offset from each other. The plurality of first pads PD1 and the plurality of second pads PD2 may be disposed to be staggered, but are not limited thereto. For example, the plurality of first pads PD1 may be located closer to the active area AA of the display panel PNL than the plurality of second pads PD2.

The cover member CG may be disposed on the display panel PNL and may have a plurality of connection lines CGL on a lower surface. The cover member CG may overlap the display panel PNL. The cover member CG may also be disposed on the chip-on-film COF. The cover member CG may overlap a part of the chip-on-film COF. The plurality of connection lines CGL may include a plurality of first connection lines CGL1 and a plurality of second connection lines CGL2 that are alternately disposed. The ends of the first connection lines CGL1 and the second connection lines CGL2 may be offset from each other, causing them to be alternately disposed. The cover member CG may be formed of a transparent material. The cover member CG may be formed of, for example, glass, but is not limited thereto. The cover member CG may be cover glass.

One ends of the plurality of connection lines CGL may be located to overlap the pad area PA of the display panel PNL. One ends of the plurality of first connection lines CGL1 and one ends of the plurality of second connection lines CGL2 may be located to overlap the pad area PA of the display panel PNL. The one ends of the plurality of first connection lines CGL1 may be located to be staggered from the one ends of the plurality of second connection lines CGL2. The one ends of the plurality of first connection lines CGL1 may be located closer to the active area AA of the display panel PNL than the one ends of the plurality of second connection lines CGL2. The one ends of the plurality of first connection lines CGL1 may overlap the plurality of first pads PD1 of the display panel PNL. The one ends of the plurality of second connection lines CGL2 may overlap the plurality of second pads PD2 of the display panel PNL.

The one ends of the plurality of connection lines CGL may be located to overlap the pads PD of the pad area PA of the display panel PNL. The one ends of the plurality of connection lines CGL of the cover member CG may be bonded with the pads PD of the pad area PA of the display panel PNL by an anisotropic conductive film ACF. The one ends of the plurality of first connection lines CGL1 may be connected to the plurality of first pads PD1 of the display panel PNL by the anisotropic conductive film ACF. The one ends of the plurality of second connection lines CGL2 may be bonded with the plurality of second pads PD2 of the display panel PNL by the anisotropic conductive film ACF.

The other ends of the plurality of connection lines CGL of the cover member CG may be located close to a lower edge of the cover member CG. The other ends of the plurality of first connection lines CGL1 and the other ends of the plurality of second connection lines CGL2 may be located close to the lower edge of the cover member CG. The other ends of the plurality of first connection lines CGL1 may be disposed to be staggered from the other ends of the plurality of second connection lines CGL2, but are not limited thereto. For example, the other ends of the plurality of second connection lines CGL2 may be located closer to the lower edge of the cover member CG than the other ends of the plurality of first connection lines CGL1.

The other ends of the plurality of connection lines CGL of the cover member CG may overlap the chip-on-film COF. The other ends of the plurality of first connection lines CGL1 and the other ends of the plurality of second connection lines CGL2 may overlap the chip-on-film COF. The other ends of the plurality of connecting lines CGL of the cover member CG may be connected to pads of the chip-on-film COF.

The chip-on-film COF may be disposed at one side of the display panel PNL so as not to overlap the display panel PNL. The chip-on-film COF may be disposed adjacent to the pad area PA of the display panel PNL so as not to overlap the display panel PNL.

Referring to FIGS. 1, 2, and 4, the chip-on-film COF may be bonded with a lower surface of the cover member CG. The chip-on-film COF may be a “2-metal chip-on-film” or a “double-sided metal chip-on-film” that implements a circuit on both surfaces. A driving chip DIC may be mounted on an upper surface of the chip-on-film COF. The chip-on-film COF may be bonded with the cover member CG in a state in which the driving chip DIC is flipped to be located thereunder. The chip-on-film COF may be bonded with the cover member CG so that a lower surface of the chip-on-film COF faces the lower surface of the cover member CG.

The chip-on-film COF may include a base film BF, a plurality of first bottom circuit lines CBL1 and second bottom circuit lines CBL2 disposed on a bottom surface of the base film BF, and a plurality of first top circuit lines CTL1, second top circuit lines CTL2, and third top circuit lines CTL3 that are disposed on a top surface of the base film BF.

The chip-on-film COF may include the plurality of first bottom circuit lines CBL1 disposed on the bottom surface of the base film BF, a plurality of first bottom pads PDL1 disposed on one ends of the plurality of first bottom circuit lines CBL1, the plurality of second bottom circuit lines CBL2 disposed to be spaced apart from the plurality of first bottom circuit lines CBL1 on the bottom surface of the base film BF, and a plurality of second bottom pads PDL2 disposed on one ends of the plurality of second bottom circuit lines CBL2.

The other ends of the plurality of connection lines CGL of the cover member CG may be connected to the bottom pads PDL of the chip-on-film COF. The other ends of the plurality of first connection lines CGL1 may be connected to the plurality of first bottom pads PDL1, and the other ends of the plurality of second connection lines CGL2 may be connected to the plurality of second bottom pads PDL2.

The other ends of the plurality of connection lines CGL of the cover member CG may be bonded with the bottom pads PD of the chip-on-film COF by the anisotropic conductive film ACF. The other ends of the plurality of first connection lines CGL1 of the cover member CG may be bonded with the plurality of first bottom pads PDL1 of the chip-on-film COF by the anisotropic conductive film ACF. The other ends of the plurality of second connection lines CGL2 of the cover member CG may be bonded with the plurality of second bottom pads PDL2 of the chip-on-film COF by the anisotropic conductive film ACF.

The chip-on-film COF may include the plurality of first top circuit lines CTL1 which are disposed one-to-one with the plurality of first bottom circuit lines CBL1 on the top surface of the base film BF and on which the driving chip DIC is mounted, and a plurality of first via holes Via1 passing through the base film BF and connecting the plurality of first top circuit lines CTL1 to the plurality of first bottom circuit lines CBL1. An area in which the plurality of first via holes Via1 are disposed may be a via hole area VAA.

The chip-on-film COF may include the plurality of second top circuit lines CTL2 which are disposed one-to-one with the plurality of second bottom circuit lines CBL2 adjacent to the plurality of first top circuit lines CTL1 on the top surface of the base film BF and on which the driving chip DIC is mounted, and a plurality of second via holes Via2 passing through the base film BF and connecting the plurality of second top circuit lines CTL2 to the plurality of second bottom circuit lines CBL2.

The chip-on-film COF may include the plurality of third top circuit lines CTL3 disposed adjacent to the plurality of second bottom circuit lines CBL2 on the top surface of the base film BF and on which the driving chip DIC is mounted, and a plurality of top pads PDT disposed on one ends of the plurality of third top circuit lines CTL3. The flexible printed circuit board FPCB may be connected to the plurality of top pads PDT of the plurality of third top circuit lines CTL3.

The driving chip DIC may be mounted on the plurality of first top circuit lines CTL1, the plurality of second top circuit lines CTL2, and the plurality of third top circuit lines CTL3 by, for example, solder bumps.

The display device according to the embodiment of the present specification may further include a sealant SL disposed between the display panel PNL and the cover member CG and covering the active area AA of the display panel PNL. The sealant SL can prevent external moisture from penetrating the active area AA of the display panel PNL and damaging light-emitting elements of the display panel PNL.

According to one embodiment of the present specification, since the double-sided circuit chip-on-film having the via hole area is bonded with the cover member instead of the pad area of the display panel, it is possible to reduce the non-active area of the display panel. That is, it is possible to reduce the size of the backplane substrate that provides the pad area of the display panel.

According to one embodiment of the present specification, it is possible to reduce the size of the backplane substrate of the display panel, thereby increasing the number of backplane substrates of the display panel that can be manufactured from a single semiconductor substrate, that is, unit per sheet (UPS) and reducing the manufacturing cost of the display device.

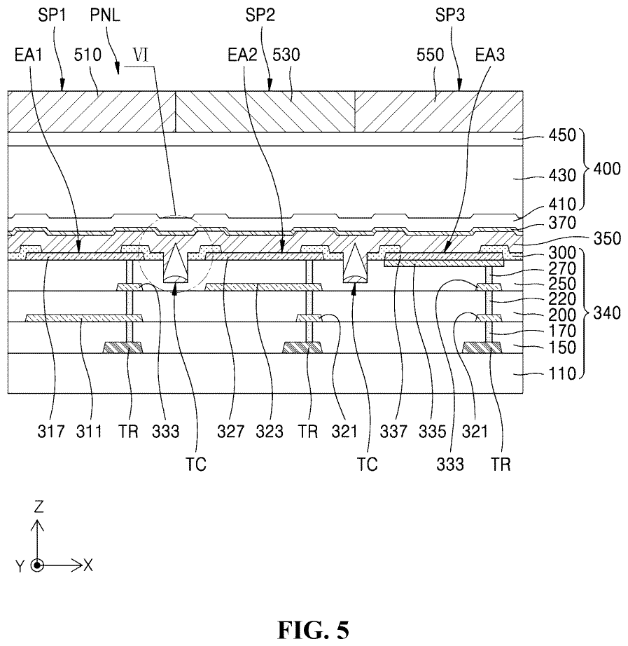

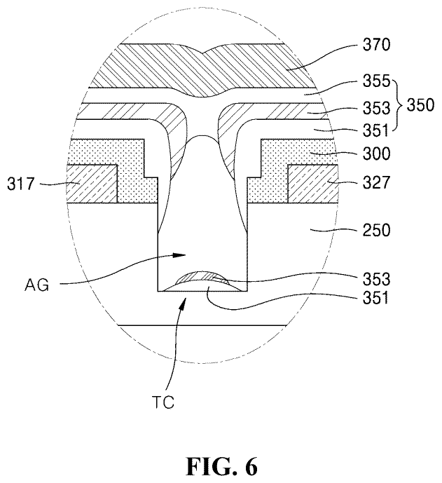

FIG. 5 is a cross-sectional view of the display panel along line V-V in FIG. 3. FIG. 6 is an enlarged view of area VI in FIG. 5. The display panel PNL according to one embodiment of the present specification may be an OLEDoS micro display panel, but is not limited thereto.

Referring to FIG. 5, the display panel PNL according to one embodiment of the present specification may include a substrate 110, a driving transistor TR, first to third insulating layers 150, 200, and 250, first to third reflective electrodes 311, 323, and 335, first and second contact electrodes 321 and 333, first to third anode electrodes 317, 327, and 337, a bank 300, an organic light-emitting layer 350, a cathode electrode 370, a trench TC, an encapsulation layer 400, and first to third color filters 510, 530, and 550. The substrate 110, the driving transistor TR, the first to third insulating layers 150, 200, and 250, the first to third reflective electrodes 311, 323, and 335, the first and second contact electrodes 321 and 333, the first to third anode electrodes 317, 327, and 337, and the bank 300 may constitute a backplane substrate 340. The backplane substrate 340 may provide the pads PD of the pad area PA.

The display panel PNL according to one embodiment of the present specification may be implemented in a so-called top emission type in which light emitted from the organic light-emitting layer 350 is emitted upward.

The substrate 110 may be formed of a semiconductor material such as silicon (Si), germanium (Ge), silicon carbide (SiC), gallium arsenide (GaAs), indium arsenide (InAs), and indium phosphide (InP). The substrate 110 may be a semiconductor substrate.

On the substrate 110, for example, the first sub-pixel SP1, the second sub-pixel SP2, and the third sub-pixel SP3 arranged in an X direction are provided. The first sub-pixel SP1 may be provided to emit red light, the second sub-pixel SP2 may be provided to emit green light, and the third sub-pixel SP3 may be provided to emit blue light. The arrangement order and direction of the sub-pixels SP1, SP2, and SP3 may be changed in various ways.

A driving circuit including various circuit lines, transistors TR, and capacitors, etc. is provided in each of the sub-pixels SP1, SP2, and SP3. The circuit lines may include gate lines, data lines, power lines, and reference lines, and the transistors TR may include switching transistors, driving transistors, and sensing transistors. For example, the switching transistor, the driving transistor, and the sensing transistor may be formed on the substrate 110 using a complementary metal-oxide-semiconductor (CMOS) process.

The switching transistor is switched according to a gate signal supplied to the gate line to supply a data voltage supplied from the data line to the driving transistor.

The driving transistor is switched according to the data voltage supplied from the switching transistor to generate a data current from power supplied from the power line and supply the data current to the anode electrodes 317, 327, and 337.

The sensing transistor serves to sense a threshold voltage difference of the driving transistor, which causes the degradation of image quality, and supplies a current of the driving transistor to the reference line in response to a sensing control signal supplied from the gate line or a separate sensing line.

The capacitor serves to retain the data voltage supplied to the driving transistor for one frame, and electrodes of the capacitor may be connected to a gate terminal and source terminal of the driving transistor, respectively.

The first insulating layer 150 may be disposed on the substrate 110. The first insulating layer 150 may be formed of an inorganic insulation material or an organic insulation material. The first insulating layer 150 may cover transistors, various signal lines, capacitors, etc., which are disposed on the substrate 110.

The first reflective electrode 311 and the first contact electrodes 321 may be disposed on the first insulating layer 150. The first reflective electrode 311 may be disposed in the first sub-pixel SP1, and the first contact electrode 321 may be disposed in each of the second sub-pixel SP2 and the third sub-pixel SP3.

First contact vias 170 may be disposed to pass through the first insulating layer 150.

In the first to third sub-pixels SP1, SP2, and SP3, the first reflective electrode 311 and the first contact electrodes 321 may each be connected to the transistor TR through the first contact vias 170 passing through the first insulating layer 150.

After the first contact vias 170 passing through the first insulating layer 150 are first formed, the first reflective electrode 311 and the first reflective electrodes 321 may be formed on the first insulating layer 150.

In one embodiment, the first reflective electrode 311 and the first contact via 170 may be formed integrally in the first sub-pixel SP1. The first contact electrode 321 and the first contact via 170 may be formed integrally in the second sub-pixel SP2. The first contact electrode 321 and the first contact via 170 may be formed integrally in the third sub-pixel SP3.

The first reflective electrode 311 and the first contact electrodes 321 may be formed of a metal material with high reflectivity, such as silver (Ag), a silver alloy, aluminum (Al), or an aluminum alloy. The first contact via 170 may contain a metal material.

The second insulating layer 200 may be disposed on the first insulating layer 150, and the second insulating layer 200 may cover the first reflective electrode 311 and the first contact electrodes 321.

The second insulating layer 200 may be formed of an inorganic insulation material or an organic insulation material.

The second reflective electrode 323 and the second contact electrodes 333 may be disposed on the second insulating layer 200.

The second reflective electrode 323 may be disposed in the second sub-pixel SP2, and the second contact electrode 333 may be disposed in each of the first sub-pixel SP1 and the third sub-pixel SP3.

Second contact vias 220 may be disposed to pass through the second insulating layer 200.

In the first sub-pixel SP1, the second contact electrode 333 may be connected to the first reflective electrode 311 through the second contact via 220 passing through the second insulating layer 200. In the second sub-pixel SP2, the second reflective electrode 323 may be connected to the first contact electrode 321 through the second contact via 220 passing through the second insulating layer 200. In the third sub-pixel SP3, the second contact electrode 333 may be connected to the first contact electrode 321 through the second contact via 220 passing through the second insulating layer 200.

The second reflective electrode 323 and the second contact electrodes 333 may be formed of a metal material having high reflectivity, such as silver (Ag), a silver alloy, aluminum (Al), or an aluminum alloy. The second contact via 220 may contain a metal material.

After the second contact vias 220 passing through the second insulating layer 200 are first formed, the second reflective electrode 323 and the second reflective electrode 333 may be formed on the second insulating layer 200.

In one embodiment, the second contact electrode 333 and the second contact via 220 may be formed integrally in the first sub-pixel SP1. The second reflective electrode 323 and the second contact via 220 may be formed integrally in the second sub-pixel SP2. The second contact electrode 333 and the second contact via 220 may be formed integrally in the third sub-pixel SP3.

The second reflective electrode 323 and the second contact electrodes 333 may be disposed on the second insulating layer 200.

The third insulating layer 250 may be disposed on the second insulating layer 200, and the third insulating layer 250 may cover the second reflective electrode 323 and the second contact electrodes 333.

The third insulating layer 250 may be formed of an inorganic insulation material or an organic insulation material.

The first anode electrode 317, the second anode electrode 327, the third reflective electrode 335, the third anode electrode 337 may be disposed on the third insulating layer 250. The first anode electrode 317 may be disposed in the first sub-pixel SP1, the second anode electrode 327 may be disposed in the second sub-pixel SP2, and the third reflective electrode 335 and the third anode electrode 337 may be disposed in the third sub-pixel SP3.

The third reflective electrode 335 and the third anode electrode 337 may come into contact with each other in the third sub-pixel SP3.

Third contact vias 270 may be disposed to pass through the third insulating layer 250.

In the first sub-pixel SP1, the first anode electrode 317 may be connected to the second contact electrode 333 through the third contact via 270 passing through the third insulating layer 250. In the second sub-pixel SP2, the second anode electrode 327 may be connected to the second reflective electrode 323 through the third contact via 270 passing through the third insulating layer 250. In the third sub-pixel SP3, the third reflective electrode 335 may be connected to the second contact electrode 333 through the third contact via 270 passing through the third insulating layer 250.

In one embodiment, instead of the third reflective electrode 335 and the third anode electrode 337 coming into contact with each other, an additional insulating layer may be further disposed on the third reflective electrode 335, and the first to third anodes electrodes 317, 327, and 337 may be disposed on the insulating layer. In this case, the third reflective electrode 335 and the third anode electrode 337 may be connected through an additional contact via.

The third reflective electrode 335 may be formed of a metal material with high reflectivity, such as silver (Ag), a silver alloy, aluminum (Al), or an aluminum alloy. The third contact via 270 may contain a metal material. The first to third anode electrodes 317, 327, and 337 may be formed of a transparent conductive material such as ITO or IZO that may transmit light.

The first to third anode electrodes 317, 327, and 337 may each be electrically connected to the source terminal or drain terminal of the driving transistor disposed on the substrate 110.

The bank 300 may be disposed to cover edge areas of the first to third anode electrodes 317, 327, and 337 on the third insulating layer 250. Parts of upper surfaces of the first to third anode electrodes 317, 327, and 337 exposed without being covered by the bank 300 become light-emitting areas.

The bank 300 may be formed of an inorganic insulation material. In one embodiment, the bank 300 may be formed of an organic insulation material.

The trench TC having a concave structure is formed in the bank 300 and the third insulating layer 250. The trench TC may pass through the bank 300 in boundary areas between the sub-pixels SP1, SP2, and SP3 and extend to a predetermined area of the third insulating layer 250. Accordingly, the trench TC may be formed through a process of removing the bank 300 and the predetermined area of the third insulating layer 250. In one embodiment, the trench TC may extend to the inside of the second insulating layer 200 below the third insulating layer 250.

The trench TC is used to disconnect at least a part of the organic light-emitting layer 350. By disconnecting at least a part of the organic light-emitting layer 350 in the trench TC, it is possible to prevent charges from moving between the neighboring sub-pixels SP1, SP2, and SP3 through the organic light-emitting layer 350, thereby preventing a leakage current from being generated between the neighboring sub-pixels SP1, SP2, and SP3.

The organic light-emitting layer 350 may be disposed in light-emitting areas EA1, EA2, and EA3 of the sub-pixels SP1, SP2, and SP3 and the boundary areas between the sub-pixels SP1, SP2, and SP3. The organic light-emitting layer 350 may be disposed on the first to third anode electrodes 317, 327, and 337 and the bank 300 and may also be disposed inside and above the trench TC.

The organic light-emitting layer 350 may be provided to emit, for example, white (W) light. To this end, the organic light-emitting layer 350 may include a plurality of stacks that emit light of different colors. In one embodiment, the organic light-emitting layer 350 may be provided to emit light of different colors for each sub-pixel. A red light-emitting layer that emits red light may be provided in the first sub-pixel SP1, a green light-emitting layer that emits green light may be provided in the second sub-pixel SP2, and a blue light-emitting layer that emits blue light may be provided in the third sub-pixel SP3.

Referring to FIG. 6, the organic light-emitting layer 350 may include a first stack 351, a second stack 355, and a charge generation layer 353 provided between the first stack 351 and the second stack 355.

The organic light-emitting layer 350 may be disposed inside and above the trench TC. When the organic light-emitting layer 350 is disposed inside the trench TC, at least a part of the organic light-emitting layer 350 may be disconnected, thereby preventing a leakage current from being generated between the adjacent sub-pixels SP1, SP2, and SP3.

The first stack 351 may be disposed on side surfaces and may also be disposed on a lower surface of the trench TC. In this case, a part of the first stack 351 formed on the side surfaces of the trench TC and a part of the first stack 351 formed on the lower surface of the trench TC are not connected. In addition, a part of the first stack 351 formed on one side surface, such as a left side surface, of the trench TC and a part of the first stack 351 formed on the other side surface, such as a right side surface, of the trench TC are not connected. Accordingly, charges cannot move between the adjacent sub-pixels SP1, SP2, and SP3 with the trench TC interposed therebetween through the first stack 351.

In addition, the charge generation layer 353 may be disposed on the first stack 351. In this case, the charge generation layer 353 may not extend to the inside of the trench TC and may be disposed only above the trench TC. In addition, the charge generation layer 353 may also be disposed on the first stack 351 disposed on the lower surface of the trench TC.

In this case, a part of the charge generation layer 353 formed on one side surface, such as the left side surface, of the trench TC and a part of the charge generation layer 353 formed on the other side, such as the right side surface, of the trench TC are not connected. Accordingly, charges cannot move between the adjacent sub-pixels SP1, SP2, and SP3 with the trench TC interposed therebetween through the charge generation layer 353.

In addition, the second stacks 355 may be connected between the adjacent sub-pixels SP1, SP2, and SP3 with the trench TC interposed therebetween on the charge generation layer 353. Accordingly, charges cannot move between the adjacent sub-pixels SP1, SP2, and SP3 with the trench TC interposed therebetween through the second stack 355. However, by appropriately adjusting the shape of the trench TC and the deposition process of the organic light-emitting layer 350, the second stacks 355 may also be disconnected between the adjacent sub-pixels SP1, SP2, and SP3 with the trench TC interposed therebetween. In particular, lower portions of the second stacks 355 adjacent to the charge generation layer 353 may be disconnected in the areas between the sub-pixels SP1, SP2, and SP3.

An air gap AG may be formed in the trench TC by the structures of the first stack 351, the charge generation layer 353, and the second stack 355. The air gap AG may be defined by the third insulating layer 250 and the organic light-emitting layer 350. The air gap AG provided below the organic light-emitting layer 350 may be defined by the third insulating layer 250, the first stack 351, the charge generation layer 353, and the second stack 355. The air gap AG may extend from the inside of the trench TC to the top of the trench TC.

The charge generation layer 353 has greater conductivity than the first stack 351 and the second stack 355. The charge generation layer 353 may include an n-type charge generation layer located adjacent to the first stack 351 and a p-type charge generation layer formed on the n-type charge generation layer and located adjacent to the second stack 355. The n-type charge generation layer may be an organic layer having an organic host material capable of the electron transport ability doped with an alkali metal, such as Li, Na, K, or Cs, or an alkaline earth metal, such as Mg, Sr, Ba, or Ra, and the p-type charge generation layer may have an organic host material capable of the hole transport ability doped with a dopant.

As described above, since the n-type charge generation layer constituting the charge generation layer 353 may be formed of a metal material, the n-type charge generation layer has greater conductivity than the first stack 351 and the second stack 355. Accordingly, charges between the adjacent sub-pixels SP1, SP2, and SP3 are moved mainly through the charge generation layer 353.

According to one embodiment of the present specification, a part of the organic light-emitting layer 350 of the display panel PNL may be disconnected from other parts of the organic light-emitting layer 350 by the trench TC when the organic light-emitting layer 350 is formed. In particular, by forming the first stack 351 and the charge generation layer 353 to be disconnected, it is possible to prevent a leakage current from being generated between the adjacent sub-pixels SP1, SP2, and SP3.

The cathode electrode 370 is formed on the organic light-emitting layer 350. Like the organic light-emitting layer 350, the cathode electrode 370 may also be disposed in the light-emitting areas EA1, EA2, and EA3 of the sub-pixels SP1, SP2, and SP3 and the boundary areas between the sub-pixels SP1, SP2, and SP3. The cathode electrode 370 is a common layer and may also be formed above the bank 300 and the trench TC.

The cathode electrode 370 may be formed of a semi-transmissive conductive material. The cathode electrode 370 may be formed of a metal material such as magnesium (Mg), silver (Ag), or an alloy of magnesium (Mg) and silver (Ag). The cathode electrode 370 may be formed in the form of a thin film having the thickness of several nanometers to tens of nanometers. Accordingly, it is possible to obtain the micro-cavity effect as light is repeatedly reflected and re-reflected between the cathode electrode 370 and the first to third reflective electrodes 317, 327, and 337.

According to one embodiment of the present specification, since a first distance between the first reflective electrode 311 and the cathode electrode 370 in the first sub-pixel SP1, a second distance between the second reflective electrode 323 and the cathode electrode 370 in the second sub-pixel SP2, and a third distance between the third reflective electrode 335 and the cathode electrode 370 in the third sub-pixel SP3 may all be configured differently, it is possible to increase light extraction efficiency of light of different colors, such as red, green, and blue light, in the sub-pixels SP1, SP2, and SP3 by the micro-cavity effect.

The encapsulation layer 400 may be disposed on the cathode electrode 370 and can prevent external moisture from penetrating and damaging the organic light-emitting layer 350. The encapsulation layer 400 may include a first inorganic encapsulation layer 410 disposed on the cathode electrode 370, an organic encapsulation layer 430 disposed on the first inorganic encapsulation layer 410, and a second inorganic encapsulation layer 450 disposed on the organic encapsulation layer 430. The first and second inorganic encapsulation layers 410 and 450 may each be selected from aluminum oxide (AlₓO_{y}), silicon oxide (SiOₓ), silicon nitride (SiNₓ), silicon oxynitride (SiON), etc.

The first to third color filters 510, 530, and 550 may be disposed on the encapsulation layer 400. The first color filter 510 overlapping the first light-emitting area EA1 may be provided in the first sub-pixel SP1, the second color filter 530 overlapping the second light-emitting area EA2 may be provided in the second sub-pixel SP2, and the third color filter 550 overlapping the third light-emitting area EA3 may be provided in the third sub-pixel SP3. The first color filter 510 may be a red color filter that emits light of red, the second color filter 530 may be a green color filter that emits light of green, and the third color filter 550 may be a blue color filter that emits light of blue.

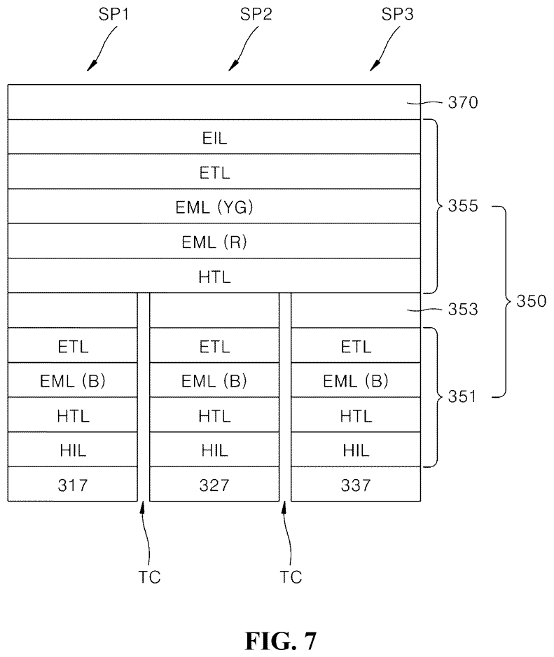

FIG. 7 is a schematic cross-sectional view of an organic light-emitting layer according to one embodiment of the present specification.

Referring to FIG. 7, the first anode electrode 317 is disposed in the first sub-pixel SP1, the second anode electrode 327 is disposed in the second sub-pixel SP2, and the third anode electrode 337 is disposed in the third sub-pixel SP3.

The organic light-emitting layer 350 is disposed on the first to third anode electrodes 317, 327, and 337. The organic light-emitting layer 350 includes the first stack 351, the second stack 355, and the charge generation layer 353.

The first stack 351 may be formed in a structure in which a hole injecting layer HIL, a hole transporting layer HTL, a blue emitting layer EML(B), and an electron transporting layer ETL are stacked sequentially. The first stack 351 is disconnected in the boundary areas between the sub-pixels SP1, SP2, and SP3, that is, the trench TC areas.

The charge generation layer 353 serves to supply charges to the first stack 351 and the second stack 355. The charge generation layer 353 may include an n-type charge generation layer for supplying electrons to the first stack 351 and a p-type charge generation layer for supplying holes to the second stack 355. As described above, the n-type charge generation layer may include a metal material as a dopant. The charge generation layer 353 is disconnected in the boundary areas between the sub-pixels SP1, SP2, and SP3, that is, the trench TC areas.

The second stack 355 may be provided on the charge generation layer 353 and formed in a structure in which a hole transporting layer HTL, a red emitting layer EML(R), a yellow green emitting layer EML(YG), an electron transporting layer ETL, and an electron injecting layer EIL are stacked sequentially. The stacking order of the red emitting layer EML(R) and the yellow green emitting layer EML(YG) may be changed.

The second stack 355 may be disposed to be connected between the sub-pixels SP1, SP2, and SP3. However, as described above, lower portions of the second stacks 355 may be disconnected in the boundary areas between the sub-pixels SP1, SP2, and SP3, that is, the trench TC areas. For example, the hole transporting layer HTL constituting the second stack 355 may be disconnected, or the hole transporting layer HTL and the red emitting layer EML(R) that constitute the second stack 355 may be disconnected. For example, the hole transporting layer HTL, the red emitting layer EML(R), and the yellow green emitting layer EML(YG) that constitute the second stack 355 may be disconnected.

The cathode electrode 370 is disposed on the organic light-emitting layer 350. The cathode electrode 370 may be formed to be connected between the sub-pixels SP1, SP2, and SP3.

The organic light-emitting layer 350 of FIG. 7 emits white light in a combination of the blue emitting layer EML(B) of the first stack and the red emitting layer EML(R) and the yellow green emitting layer EML(YG) of the second stack 355.

In one embodiment, the second stack 355 may include only the yellow green emitting layer EML(YG). In this case, white light is emitted in a combination of the blue emitting layer EML(B) of the first stack 351 and the yellow green emitting layer EML(YG) of the second stack 355.

In one embodiment, the green emitting layer EML(G) may be formed instead of the yellow green emitting layer EML(YG) of the second stack 355. In this case, the organic light-emitting layer 350 emits white light in a combination of the blue emitting layer EML(B) of the first stack 351 and the red emitting layer EML(R) and green emitting layer EML(G) of the second stack 355.

In one embodiment, the first stack 351 may include the red emitting layer EML(R) and the yellow green emitting layer EML(YG), and the second stack 355 may include the blue emitting layer EML(B). In one embodiment, the first stack 351 may include the red emitting layer EML(R) and the green emitting layer EML(G), and the second stack 355 may include the blue emitting layer EML(B).

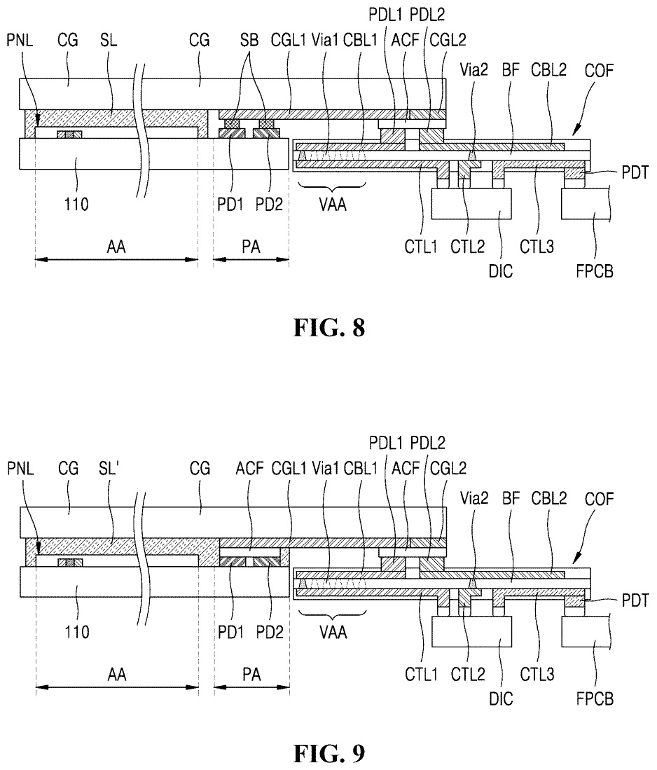

FIG. 8 is a schematic plan view of the display device according to the embodiment of the present specification.

Referring to FIG. 8, one ends of the plurality of connection lines CGL of the cover member CG may be bonded with the pads PD of the pad area PA of the display panel PNL by solder bumps SB instead of the anisotropic conductive film ACF. The other ends of the plurality of connection lines CGL of the cover member CG may also be bonded with the bottom pads PDL of the chip-on-film COF by the anisotropic conductive film ACF.

In one embodiment, the other ends of the plurality of connection lines CGL of the cover member CG may also be bonded with the bottom pads PDL of the chip-on-film COF by the solder bumps SB instead of the anisotropic conductive film ACF.

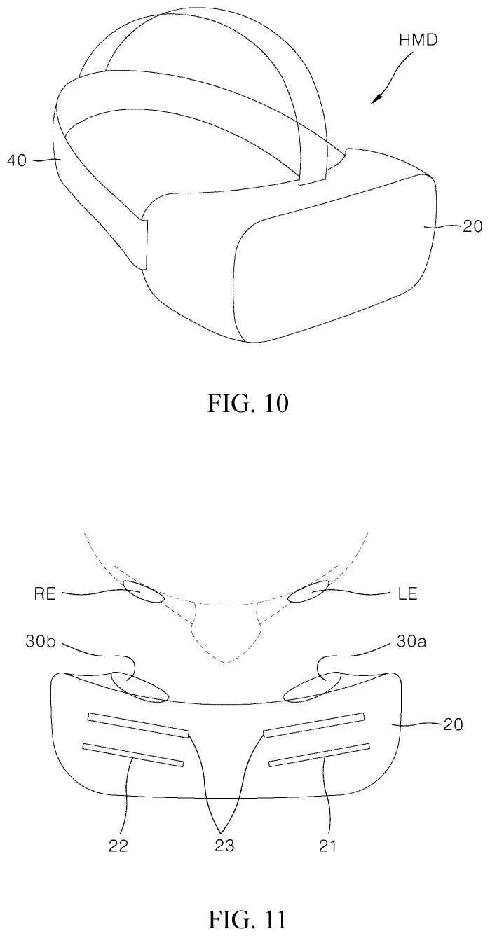

FIG. 9 is a schematic plan view of the display device according to the embodiment of the present specification.

Referring to FIG. 9, the sealant SL′ may cover both the active area AA of the display panel PNL and the pad area PA of the display panel PNL. The sealant SL′ can prevent external moisture from penetrating the pad area PA of the display panel PNL, thereby firmly maintaining the bonding between the connection lines CGL of the cover member CG and the pads PD of the display panel PNL.

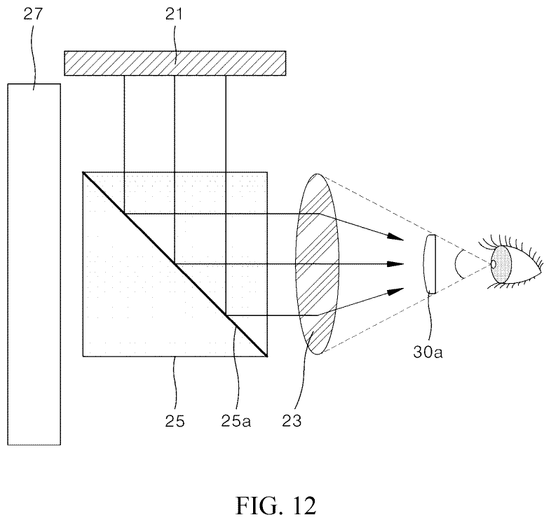

FIGS. 10 to 12 show a head mounted display device according to one embodiment of the present specification.

FIG. 10 is a schematic perspective view of the head mounted display device according to one embodiment of the present specification. FIG. 11 is a schematic view showing a head mounted display device that implements virtual reality (VR), and FIG. 12 is a schematic view showing a head mounted display device that implements augmented reality (AR).

Referring to FIG. 10, the head mounted display device according to one embodiment of the present specification includes a storage case 20 and a head mounting band 40.

The storage case 20 stores components, such as a display device, a lens array, and an eyepiece, therein.

The head mounting band 40 is fixed to the storage case 20. An example in which the head mounting band 40 is formed to surround an upper surface and both side surfaces of a user's head, but the embodiments of the present specification are not limited thereto. The head mounting band 40 is used to fix the head mounted display to the user's head and may be replaced with a structure in the form of a glasses frame or a helmet.

Referring to FIG. 11, the head mounted display device that implements VR includes a left-eye display device 21, a right-eye display device 22, a lens array 23, a left-eye eyepiece 30a, and a right-eye eyepiece 30b.

The left-eye display device 21, the right-eye display device 22, the lens array 23, the left-eye eyepiece 30a, and right-eye eyepiece 30b are stored in the storage case 20.

The left-eye display device 21 and the right-eye display device 22 may display the same image, and in this case, the user may view 2D images. Alternatively, the left-eye display device 21 may display left-eye images, and the right-eye display device 22 may display right-eye images, and in this case, the user may view three-dimensional images. Each of the left-eye display device 21 and the right-eye display device 22 may be one of the display devices according to the embodiments of the present specification.

The lens array 23 may be spaced apart from each of the left-eye eyepiece 30a and the left-eye display device 21 and provided between the left-eye eyepiece 30a and the left-eye display device 21. That is, the lens array 23 may be located in front of the left-eye eyepiece 30a and behind the left-eye display device 21. In addition, the lens array 33 may be spaced apart from each of the right-eye eyepiece 30b and the right-eye display device 22 and provided between the right-eye eyepiece 30b and the right-eye display device 22. That is, the lens array 23 may be located in front of the right-eye eyepiece 30b and behind the right-eye display device 22.

The lens array 23 may be a microlens array. The lens array 23 may be replaced with a pin hole array. Due to the lens array 23, enlarged images displayed on the left-eye display device 21 or the right-eye display device 22 may be visible to the user.

The user's left eye LE may be located behind the left-eye eyepiece 30a, and the user's right eye RE may be located behind the right-eye eyepiece 30b.

Referring to FIG. 12, the head mounted display device that implements the AR includes the left-eye display device 21, the lens array 23, the left-eye eyepiece 30a, a transmissive reflector 25, and a transmissive window 27. In FIG. 12, only a configuration of the left-eye side is shown for convenience, and a configuration of the right-eye side is also the same or similar to that of the left-eye side.

The left-eye display device 21, the lens array 23, the left-eye eyepiece 30a, the transmissive reflector 25, and the transmissive window 27 are stored in the storage case 20.

The left-eye display device 21 may be disposed at one side, for example, an upper side of the transmissive reflector 25 without covering the transmissive window 27. Accordingly, the left-eye display device 21 may provide an image to the transmissive reflector 25 without covering an external background visible through the transmissive window 27.

The left-eye display device 21 may be one of the display devices according to the embodiments of the present specification.

The lens array 23 may be provided between the left-eye eyepiece 30a and the transmissive reflector 25.

The user's left eye is located behind the left-eye eyepiece 30a.

The transmissive reflector 25 is disposed between the lens array 23 and the transmissive window 27. The transmissive reflector 25 may include a reflective surface 25a that transmits some of light and reflects the others of the light. The reflective surface 25a includes a semi-transmissive metal film. The semi-transmissive metal film may be formed of a semi-transmissive metal material such as magnesium (Mg), silver (Ag), or an alloy of magnesium (Mg) and silver (Ag). The reflective surface 25a is formed so that the image displayed on the left-eye display device 21 proceeds to the lens array 23.

Therefore, the user may view both the external background visible through the transmissive window 27 and the images displayed by the left-eye display device 21. That is, since the user may view the real background and the virtual image as one image by allowing the real background and the virtual image to overlap each other, the AR may be implemented.

What is claimed is:

1. A display device comprising:
a display panel including an active area and a pad area disposed at one side of the active area;
a cover member disposed on the display panel, the cover member having a plurality of connection lines on a lower surface; and
a chip-on-film which is bonded with the lower surface of the cover member and on which a driving chip is mounted,
wherein a first end of each of the plurality of connection lines is connected to a corresponding one of a plurality of pads in the pad area of the display panel, and a second end of each of the plurality of connection lines is connected to a corresponding one of a plurality of pads of the chip-on-film.

2. The display device of claim 1, wherein the chip-on-film is disposed at one side of the display panel so as not to overlap the display panel.

3. The display device of claim 1, wherein the chip-on-film includes:
a base film;
a plurality of first bottom circuit lines disposed on a lower surface of the base film;
a plurality of first bottom pads disposed on one ends of the plurality of first bottom circuit lines;
a plurality of second bottom circuit lines disposed to be spaced apart from the plurality of first bottom circuit lines on the bottom surface of the base film; and
a plurality of second bottom pads disposed on one ends of the plurality of second bottom circuit lines.

4. The display device of claim 3, wherein the plurality of connection lines of the cover member include a plurality of first connection lines and a plurality of second connection lines that are alternately disposed such that ends of the first connection lines and the second connection lines are offset from each other, and
ends of the plurality of first connection lines are connected to the plurality of first bottom pads, and ends of the plurality of second connection lines are connected to the plurality of second bottom pads.

5. The display device of claim 3, further comprising a plurality of first top circuit lines which is disposed one-to-one with the plurality of first bottom circuit lines on a top surface of the base film and on which a driving chip is mounted; and
a plurality of first via holes passing through the base film and connecting the plurality of first top circuit lines to the plurality of first bottom circuit lines.

6. The display device of claim 1, wherein the second end of each of the plurality of connection lines of the cover member is bonded with a corresponding one of the pads of the pad area of the display panel by an anisotropic conductive film.

7. The display device of claim 1, wherein the first end of each of the plurality of connection lines of the cover member is bonded with a corresponding one of the pads of the pad area of the display panel by a solder bump.

8. The display device of claim 1, further comprising a sealant which is disposed between the display panel and the cover member and covers the active area of the display panel.

9. The display device of claim 8, wherein the sealant covers the pad area of the display panel.

10. The display device of claim 1, wherein the display panel includes: a semiconductor substrate; a transistor disposed on the semiconductor substrate; an anode electrode connected to the transistor; an organic light-emitting layer disposed on the anode electrode; and a cathode electrode disposed on the organic light-emitting layer.

11. A display device comprising:
a display panel including an active area and a pad area disposed at one side of the active area;
a cover member disposed on the display panel; and
a chip-on-film electrically connected to the pad area of the display panel through the cover member.

12. The display device of claim 11, wherein a plurality of connection lines are disposed on a lower surface of the cover member, and
the plurality of connection lines are bonded with pads of the pad area of the display panel.

13. The display device of claim 12, wherein the chip-on-film is a double-sided circuit chip-on-film having circuit lines on both surfaces of a base film, and
the chip-on-film is disposed at one side of the display panel so as not to overlap the display panel.

14. The display device of claim 13, wherein the pads located on a bottom surface of the base film are bonded with the plurality of connection lines of the cover member.

15. The display device of claim 11, further comprising a sealant which is disposed between the display panel and the cover member and covers the active area of the display panel.

16. The display device of claim 15, wherein the sealant covers the pad area of the display panel.

17. A display device comprising:
a display panel including an active area and a pad area disposed at one side of the active area;
a cover member disposed on the display panel; and
a chip-on-film bonded with a lower surface of the cover member, the chip-on-film having a via hole area including a plurality of via holes,
wherein the via holes of the chip-on-film and the pad area of the display panel are non-overlapping in a plan view of the display device.

18. The display device of claim 17, wherein a portion of the cover member overlaps the via hole area of the chip-on-film in the plan view of the display device.

19. The display device of claim 17, further comprising a plurality of connection lines disposed on the lower surface of the cover member, the plurality of connection lines bonded with corresponding pads of the pad area of the display panel and corresponding pads of the chip-on-film.
